(19) United States
(12) Patent Application Publication
(10) Pub. No.: US 2025/0244423 A1
(43) Pub. Date: Jul. 31, 2025

(54) INFORMATION PROCESSING DEVICE AND CONTROL APPARATUS

(71) Applicant: Premo, Inc., Tokyo (JP)

(72) Inventor: Hidenori TSUJI, Tokyo (JP)

(21) Appl. No.: 19/183,904

(22) Filed: Apr. 20, 2025

Related U.S. Application Data
(63) Continuation of application No. PCT/JP2023/024681, filed on Jul. 3, 2023.

(51) Int. Cl. G01R 33/36

(52) U.S. Cl. CPC G01R 33/3642

(57) ABSTRACT

There is provided an information processing device including: a first coil; a second coil; and a calculation unit which calculates a state of a substance by detecting a state of communication between the first coil and the second coil, in which the substance is arranged in a gap between the first coil and the second coil, and the state of communication is associated with a change in the substance. There is provided an information processing device including: a first coil; a second coil; a support portion which supports the first coil and the second coil; and a calculation unit which detects a state of communication between the first coil and the second coil, and calculates a state of a substance that is arranged between the first coil and the second coil, in which the state of communication is associated with the state of the substance in advance.

The contents of the following patent application(s) are incorporated herein by reference: NO. PCT/JP2023/024681 filed in WO on Jul. 3, 2023.

### BACKGROUND

### 1. Technical Field

The present invention relates to an information processing device and a control apparatus.

### 2. Related Art

Patent Document 1 discloses a pressure sensor.

### PRIOR ART DOCUMENTS

### Patent Document

Patent Document 1: Japanese Patent Application Publication No. H6-137978

### BRIEF DESCRIPTION OF THE DRAWINGS

FIG. 1 schematically shows a control apparatus 10 according to the present embodiment.

FIG. 2 schematically shows an information processing device 20 having two chips 100, 200 which are separate from each other.

FIG. 3 is an equivalent circuit showing characteristics of a transmitting coil 110 of the chip 100 and a receiving coil 212 of the chip 200.

FIG. 4 schematically shows a side view of the information processing device 20.

FIG. 5 schematically shows relationships between a substance 82 that is calculated by the information processing device 20, and the chips 100, 200.

FIG. 6 shows an example of a relationship between a communication distance x and a coupling coefficient k.

FIG. 7 shows an example of a voltage that is induced in a receiving coil 212.

FIG. 8 schematically shows an information processing device 22 having two chips 102, 202 which are separate from each other.

FIG. 9 schematically shows another information processing device 24 having two chips 100, 200 which are separate from each other.

FIG. 10 schematically shows another information processing device 25 having two chips 100, 200 which are separate from each other.

FIG. 11 schematically shows an information processing device 26 having three or more chips which are separate from each other.

FIG. 12 schematically shows another information processing device 27 having two chips 100, 200 which are separate from each other.

FIG. 13 schematically shows an information processing device 28 having three or more chips which are separate from each other.

FIG. 14 schematically shows an information processing device 29 for which the chip 100, and a control unit 30 other than the chip, are used.

FIG. 15 shows another example of an outer shape of a chip 90.

FIG. 16 shows another example of an outer shape of a chip 92.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

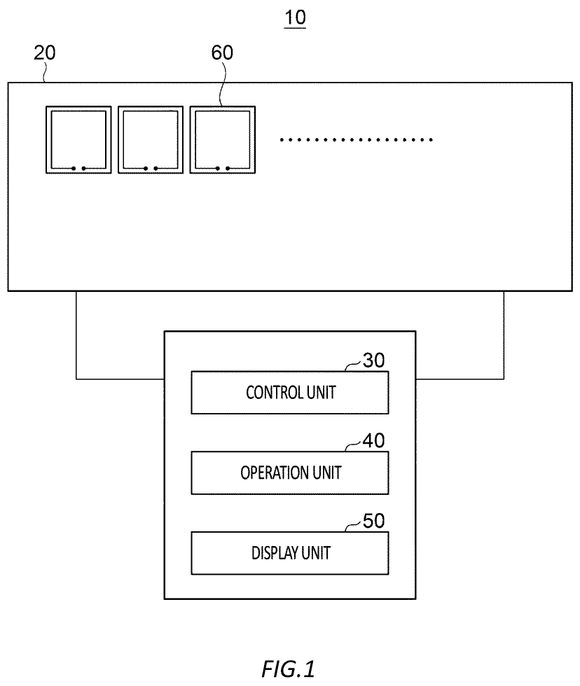

FIG. 1 schematically shows a control apparatus 10 according to the present embodiment. The control apparatus 10 includes an information processing device 20 which has a plurality of chips 60, a control unit 30 which controls a state of a substance, an operation unit 40 which is operated by a user, and a display unit 50 which displays the state of the substance or the like.

The information processing device 20 uses the plurality of chips 60 to calculate the state of the substance, and has a function as a measurement unit. The control unit 30 controls the state of the substance based on information on the state of the substance calculated by the information processing device 20. The control unit 30, the operation unit 40, and the display unit 50 may be, for example, an information processing device such as a personal computer. Calculating the state of the substance means calculating one or more values or an amount of change regarding, for example, a volume, a temperature, a vibration, a pressure, an electromagnetic wave, a sound volume, humidity, or the like.

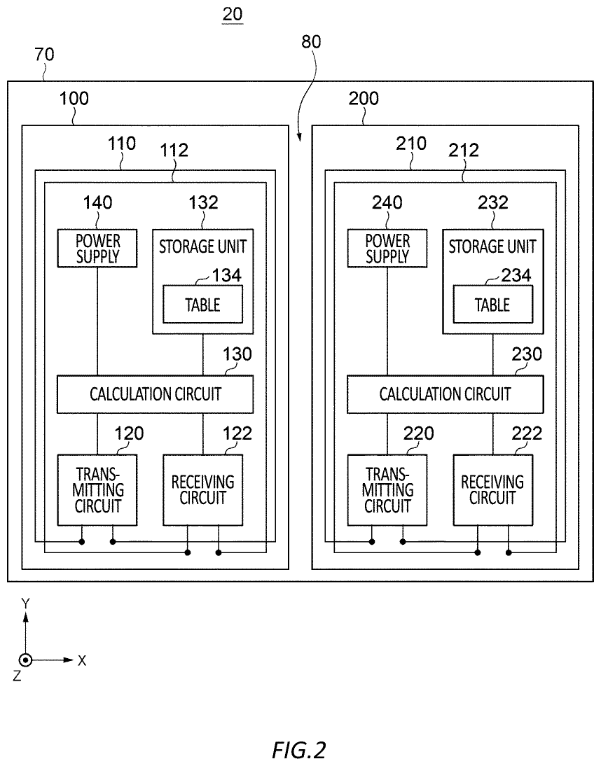

FIG. 2 schematically shows the information processing device 20 having two chips 100, 200 which are separate from each other. The information processing device 20 includes a support member 70, and the chip 100 and the chip 200 which are supported by the support member 70 with a gap 80 therebetween. The chip 100 and the chip 200 communicate with each other by magnetic field coupling. The communication by the magnetic field coupling means a transmitting method that uses a principle of electromagnetic induction to transmit information. In addition, the communication by the magnetic field coupling includes communication by inductive coupling, and communication by magnetic resonance in which a resonance phenomenon of transmitting and receiving coils is used.

The chip 100 includes a transmitting coil 110, a transmitting circuit 120 which supplies a signal to the transmitting coil 110, a calculation circuit 130 which performs a calculation on the signal, a storage unit 132 which stores a table 134 for the signal, a receiving coil 112, a receiving circuit 122 which detects a signal generated in the receiving coil 112, and a power supply 140 which supplies power to the calculation circuit 130 or the like.

The chip 100 has a rectangular plate-like outer shape. In the chip 100, the transmitting coil 110 and the receiving coil 112 are arranged to surround an outer periphery part of a main body of the chip, and are substantially rectangular. In addition, the transmitting circuit 120, the calculation circuit 130, the receiving circuit 122, and the power supply 140 are arranged inside the transmitting coil 110 and the receiving coil 112. A surface on which the transmitting coil 110 and the receiving coil 112 are wound is parallel to a main surface of the chip 100.

The power supply 140 is configured to have at least any of a power receiving function of receiving power from an outside of the chip, a power storage function of storing power inside the chip, or a power generation function of generating power inside the chip. In addition, the calculation circuit 130 may be configured with a CPU, for example.

Similarly, the chip 200 includes a transmitting coil 210, a transmitting circuit 220, a calculation circuit 230, a storage unit 232 which stores a table 234, a receiving coil 212, a receiving circuit 222, and a power supply 240. In the present embodiment, the chip 200 has the same configuration as that of the chip 100 unless otherwise specified, and thus the description thereof will be omitted.

As shown in FIG. 2, the chips 100 and 200 are arranged in positions close to each other, thereby enabling a wireless communication in which the magnetic field coupling is used between the coils. Regarding the configuration described above, the chips 100, 200 are formed on a semiconductor substrate, and are formed as an IC by being molded with resin. A length of one side of each of the chips 100, 200, and the coil is able to be reduced to approximately 300 μm, and a distance between the coils of the adjacent chips is able to be reduced to approximately 40 μm.

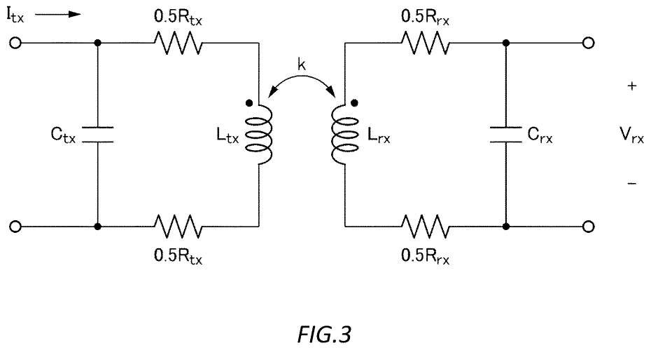

FIG. 3 is an equivalent circuit showing characteristics of the transmitting coil 110 of the chip 100 and the receiving coil 212 of the chip 200. A voltage Vrx on a receiving side is obtained by multiplying a first-order differential waveform of a transmitting current Itx by secondary low-pass filter characteristics on a transmitting side and the receiving side. In addition, a low-pass filter characteristic on the transmitting side is represented by resistance Rtx, capacitance Ctx, and inductance Ltx; a low-pass filter characteristic on the receiving side is represented by resistance Rrx, capacitance Crx, and inductance Lrx; and in addition, an amplitude of the voltage Vrx on the receiving side is proportional to the transmitting current Itx and a coupling coefficient k. For example, when a signal is transmitted from the chip 100 to the chip 200, the calculation circuit 130 of the chip 100 reads out, from the storage unit 132, the signal to be transmitted; and causes the current Itx in accordance with the signal to flow from the transmitting circuit 120 to the transmitting coil 110. The voltage Vrx is generated in the receiving coil 212 of the chip 200 due to inductive coupling with the transmitting coil 110, and the voltage Vrx is detected by the receiving circuit 222 and is read by the calculation circuit 230 as a signal.

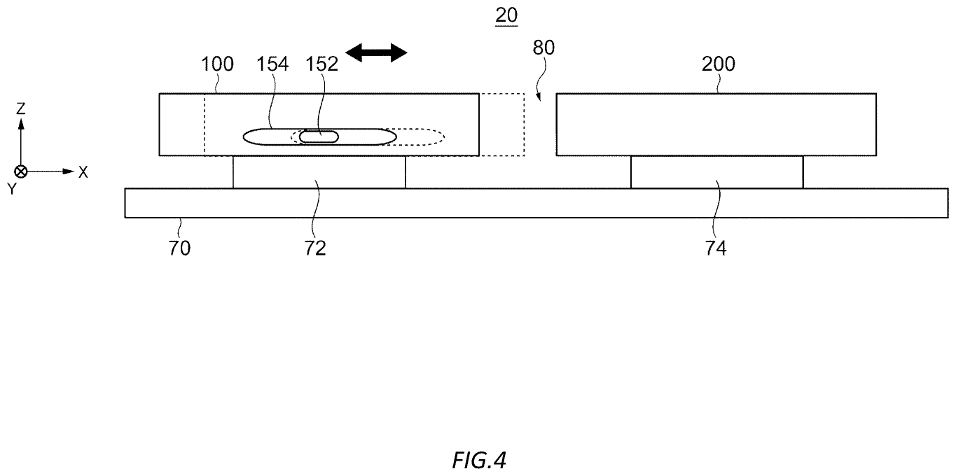

FIG. 4 schematically shows a side view of the information processing device 20. The chip 100 has a long hole 154 on a side surface. A protrusion 152 which is provided in a connection member 72 arranged on the support member 70 and which is flat, is inserted into the long hole 154. This makes it possible for the chip 100 to be movable in an x direction in the figure, which is a direction of the main surface of the chip 100. On the other hand, the chip 200 is fixed to a connection member 74 arranged on the support member 70. Accordingly, the chip 100 becomes relatively close to or far away from the chip 200 in the directions of their respective main surfaces. In this case, it is preferable that they do not come into contact with each other even in a state in which they are closest to each other, that is, the gap 80 exists.

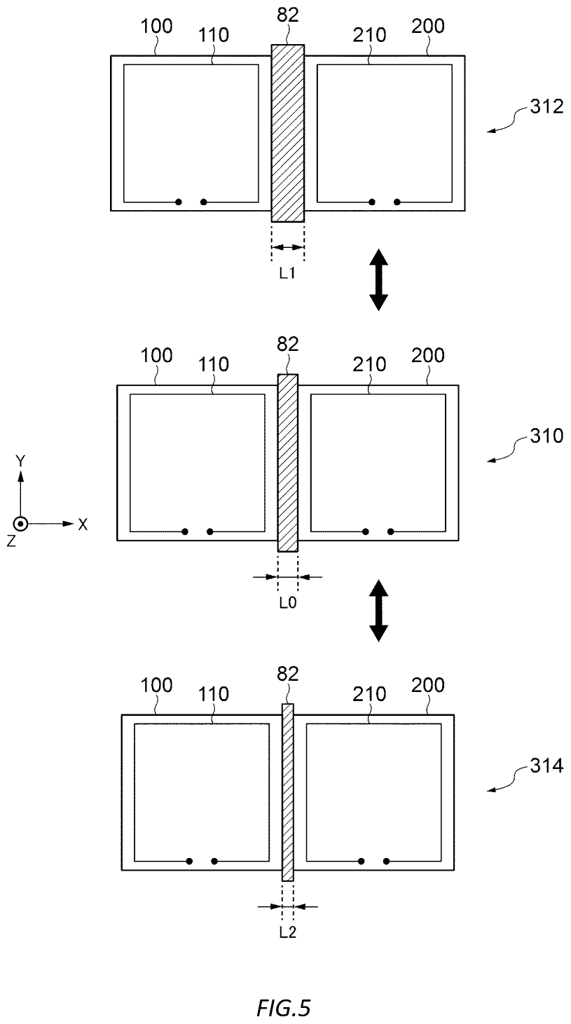

FIG. 5 schematically shows relationships between a substance 82 that is calculated by the information processing device 20, and the chips 100, 200. An example of the substance 82 is a substance of which the volume is changed by the temperature or the pressure. The substance 82 is sandwiched between side surfaces of the chips 100, 200 which face each other. For example, the substance 82 may be adhered to both side surfaces. A state 310 is a steady state in which the substance 82 is sandwiched between the chip 100 and the chip 200 with an initial width L0. When the substance 82 expands from the steady state to a width L1, the chip 100 moves in a direction away from the chip 200 as shown in a state 312. On the other hand, when the substance 82 contracts from the steady state to a width L2, the chip 100 moves in a direction approaching the chip 200 as shown in a state 314.

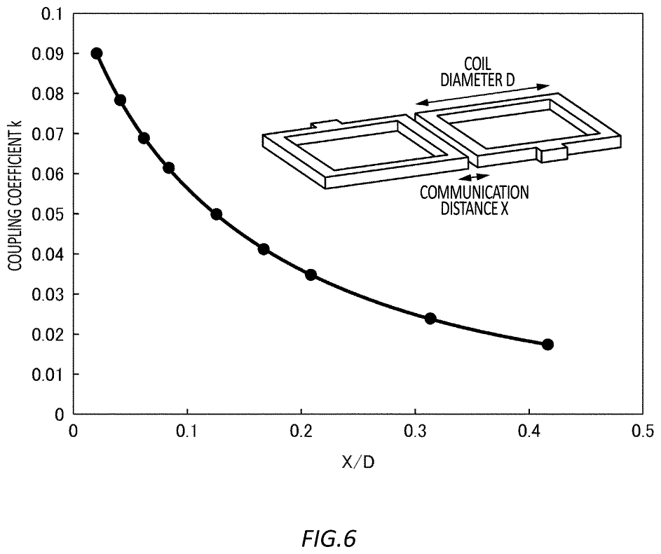

FIG. 6 shows an example of a relationship between a communication distance x and a coupling coefficient k. As shown in FIG. 6, when a coil diameter D is constant, the coupling coefficient k is decreased monotonically with respect to the communication distance x. Here, there is a positive correlation between the coupling coefficient k and a voltage Vr on the receiving side which is generated by the magnetic field coupling.

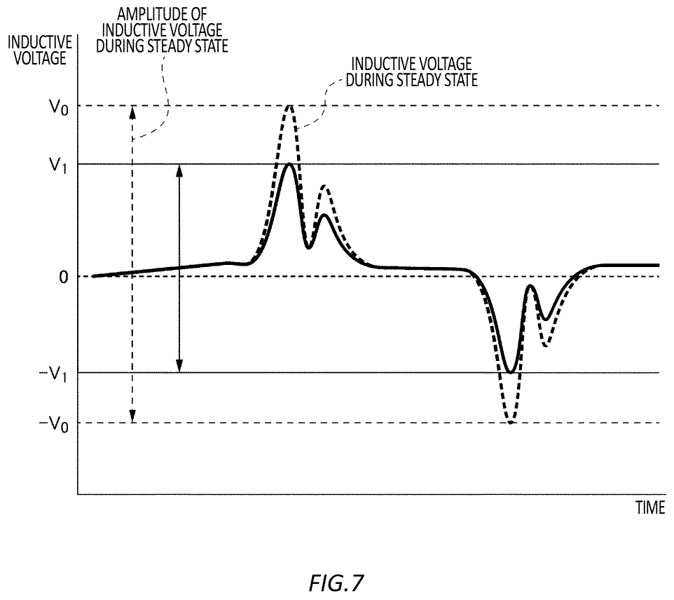

FIG. 7 shows an example of a voltage that is induced in the receiving coil 212. FIG. 7 shows a case where one rectangular pulse signal is transmitted from the chip 100. The dashed line corresponds to the state 310 in FIG. 4 as a steady state, and the solid line corresponds to the state 312.

As shown in FIG. 7, positive inductive voltages V0, V1 are induced in the receiving coil 212 in response to rising of the rectangular pulse signal, and negative inductive voltages −V0, −V1 are induced in response to falling. Absolute values of these inductive voltages are smaller in the state 312 in which the distance between the chips is far than in the state 310 in which the distance between the chips is close (V0>V1).

Therefore, by storing, in advance in the table 234 as a numerical value, a relationship between the voltage Vr on the receiving side and a distance x′ between the chips, it is possible for the calculation circuit 230 to calculate the distance x′ between the chip 100 and the chip 200 with reference to the table 234 based on the voltage Vr detected by the receiving circuit 222. Here, the distance x′ is obtained by subtracting, from the communication distance x, the outer periphery part of the chip outside the coil. The relative position of each coil to the outer periphery of the chip is fixed, and thus by calculating the distance x′ between chip 100 and the chip 200, it is possible to calculate the expansion and the contraction as an example of the state of the substance 82, and as a result, it is possible to calculate an increase or a decrease in volume.

Additionally, it is not a state of the support member 70 that is calculated, but the state of the substance 82 which is separate from the support member 70 and which exists between the chip 100 and the chip 200. It should be noted that as the voltage Vr on the receiving side, either the positive inductive voltage corresponding to the rising of the pulse signal or the negative inductive voltage corresponding to the falling may be used; a difference between them may be used; or an average value of them may be used.

The calculation circuit 230 sets the received signal as High when the induced voltage that is positive becomes greater than a predetermined threshold value; and sets the received signal as Low when the subsequently induced voltage that is negative becomes smaller than a predetermined threshold value. This makes it possible to transmit and receive a digital signal between the chips 100, 200. For example, it is conceivable that based on a voltage expected to be excited on the receiving side when the chips 100, 200 are spaced apart farthest from each other, the predetermined threshold value is set to be slightly lower than the voltage, or the like. Additionally, a magnitude of the induced voltage can be said to be a strength of the received signal, and can also be said to be an example of a state of communication.

As described above, with the present embodiment, based on the voltage Vr associated with the distance x′ between the chips 100, 200, it is possible to measure the state of the substance 82 that exists between the chips. The chips 100, 200 communicate without using wiring, and thus a reduction in size is possible. Further, it is possible to narrow the distance between the chips 100, 200, and thus it is possible to measure a detailed change in the state of the substance 82.

The chip 200 may use the transmitting coil 210 to transmit a signal indicating the state of the substance 82, which is a result of the calculation by the calculation circuit 230, to an outside, for example, the control unit 30 of the control apparatus 10. The control apparatus 10 may display the received signal on the display unit 50 such that the state of the substance 82 can be visually recognized by the user.

In this case, in addition to the signal indicating the state of the substance 82, the chip 200 may also transmit information specific to the chip 200, such as a position at which the chip 200 is arranged and identification information assigned to the chip 200. The position, the identification information, or the like may be stored in advance in the storage unit 232 to be read by the calculation circuit 230. In addition, the calculation results described above may be output to the outside via the plurality of chips 60, by sequentially transmitting and receiving the calculation results between three or more adjacent chips 60 in a so-called bucket brigade method.

FIG. 7 shows an example in which one rectangular pulse signal is transmitted and received; however, the signal is not limited to this. For example, the signal may be a triangular wave, and a plurality of pulses may be used. Further, the signal may be a signal for expressing, by widths and the number of pulses, information specific to the chip 100 such as an identification number stored in the storage unit 132 of the chip 100. In this case, for example, it is preferable that a pulse cycle is approximately 0.2 ns, which is short enough to detect the change in the state of the substance 82.

The table 234 describes an example showing the relationship between the voltage Vr on the receiving side and the distance x′ between the chips. Instead of this, when there is a correlation such as a monotonic increase or monotonic decrease between the expansion and the contraction of the substance 82, and another physical quantity, the physical quantity may be calculated as the state of the substance 82 by using the table 234 showing a relationship between the voltage Vr on the receiving side and the physical quantity. For example, in a case where the substance 82 has a property of expanding as the temperature increases, the voltage Vr on the receiving side may be associated with the temperature of the substance 82 in advance in the table 234, and the calculation circuit 230 may calculate and output the temperature of the substance 82 from the received voltage Vr with reference to the table 234.

In the table 234, mathematical expressions may be associated instead of the numerical values being associated. In addition, the table 234 may be able to be rewritten from the outside. In addition, the calculation circuit 230 may output a change in the state instead of the state itself, such as the width of the substance 82 shown in the table 234. For example, in the table 234, a voltage V1 on the receiving side in the state 312 with respect to a voltage V0 on the receiving side in the state 310 in FIG. 5 may be associated with a difference (L1-L0) in the width of the substance 82 in these states; and the calculation circuit 230 may output the difference (L1-L0) in the width as the change in the state of the substance 82. In this way, a plurality of mathematical expressions, tables, and the like may be stored to calculate the state of the substance 82, and the calculation unit 230 may select one or more of them as appropriate. In addition, the calculation unit 230 may calculate a plurality of values, such as the temperature and the pressure, for the same change in the state of the substance 82.

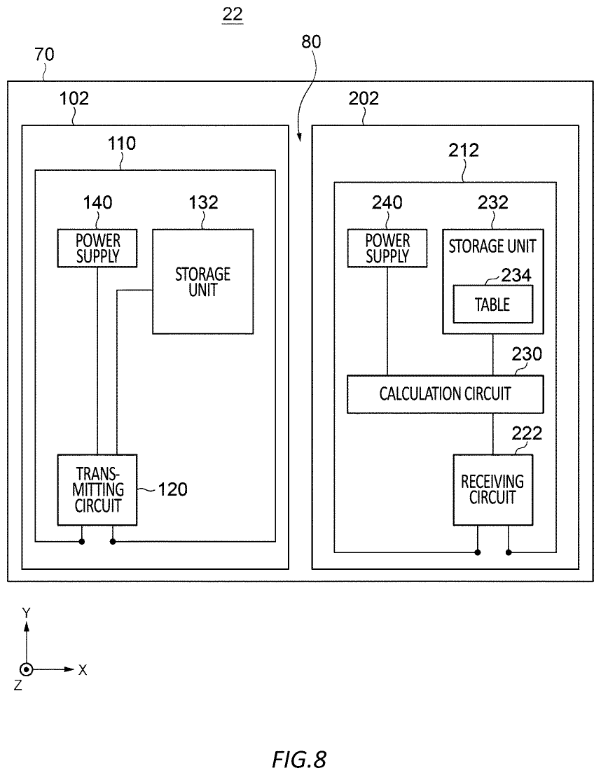

FIG. 8 schematically shows another information processing device 22 having two chips 102, 202 which are separate from each other. In the information processing device 22, the same configurations as those in the information processing device 20 are given the same reference signs numerals and the description thereof will be omitted.

The chip 102 of the information processing device 22 includes the transmitting coil 110, the transmitting circuit 120 which supplies a signal to the transmitting coil 110, the storage unit 132 which stores the table 134 for the signal, and the power supply 140 which supplies power to the calculation circuit 130 or the like. On the other hand, the chip 202 includes the calculation circuit 230 which performs a calculation on the signal, the storage unit 232 which stores the table 234 for the signal, the receiving coil 212, the receiving circuit 222 which detects a signal generated in the receiving coil 212, and the power supply 240 which supplies power to the calculation circuit 230 or the like.

The chip 102 is a chip on the transmitting side, and the chip 202 is a chip on the receiving side, and communication is performed from the chip 102 to the chip 202 by the magnetic field coupling. In the information processing device 22, as well, it is possible to calculate the state of the substance existing in the gap 80 based on the voltage Vr, on the receiving side, which is based on the distance between the chips 102, 202.

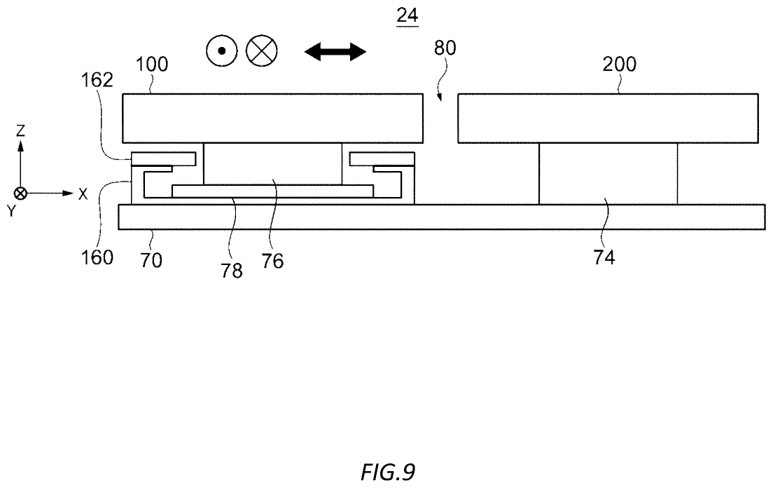

FIG. 9 schematically shows another information processing device 24 having two chips 100, 200 which are separate from each other. In the information processing device 24, the same configurations as those in the information processing device 20 are given the same reference signs numerals and the description thereof will be omitted.

In the information processing device 24, a flange portion 78 is provided on a bottom surface of the chip 100 via a connection member 76 of a columnar shape. The support member 70 is provided with a wall portion 160 which houses the flange portion 78, and a lid portion 162 which is provided on an upper surface of the wall portion 160 and protrudes beyond the wall portion 160 toward a connection member 76 side. There are gaps in XY directions between the wall portion 160 and the flange portion 78, and between the lid portion 162 and the connection member 76. Therefore, in a range in which the wall portion 160 and the flange portion 78, or the lid portion 162 and the connection member 76 do not come into contact with each other, the chip 100 can move freely in the XY directions, that is, in directions of the main surface of the chip 100. In addition, an opening for the lid portion 162 is narrower than that for the flange portion 78, and thus it is possible to prevent the flange portion 78 from slipping out of the opening.

In the information processing device 24, as well, it is possible to measure the state of the substance existing in the gap 80 between the chips 100, 200 by the distance between them. Further, in a case where the chips 100, 200 are structured to be able to be vibrated in a Y direction, the coupling coefficient k is also changed due to deviations of the chips 100, 200 in the Y direction, and thus it is possible to measure the state of the substance in relation to the Y direction.

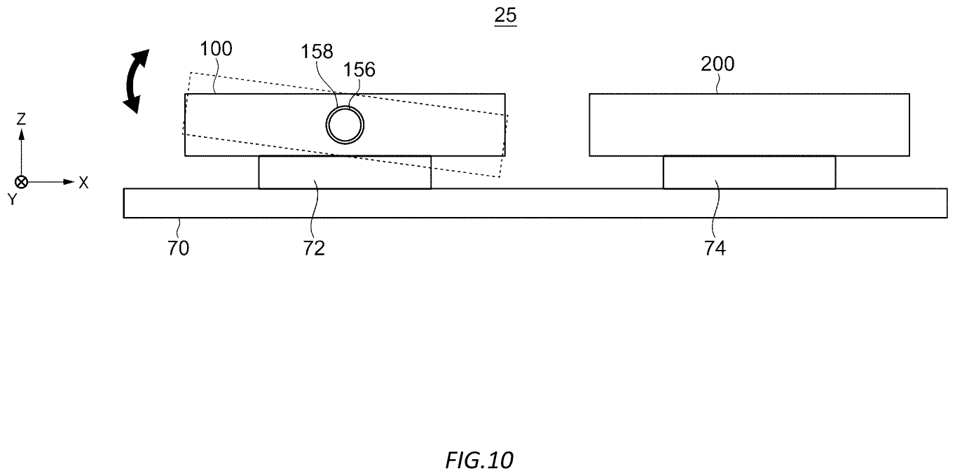

FIG. 10 schematically shows another information processing device 25 having two chips 100, 200 which are separate from each other. In the information processing device 25, the same configurations as those in the information processing device 20 are given the same reference signs numerals and the description thereof will be omitted.

A shaft 156 extends from the connection member 72 in the Y direction, and is inserted into a bearing 158 provided in the chip 100. This makes it possible for the chip 100 to be rotated about the shaft 156 in an XZ plane.

In the information processing device 25, in a state in which the main surface of the chip 100 is rotated up or down from a steady state in the XY plane, the coupling coefficient k is changed. Therefore, in the information processing device 25 as well, by previously associating the voltage Vr that is induced on the receiving side, with an angle θ of rotation, it is possible to calculate the angle θ from the voltage Vr. Further, when there is a specific correlation between the state of the substance between the chips 100, 200, and the angle θ of the chip 100, by associating them with each other in advance, it is possible to calculate the state of the substance from the voltage Vr. It should be noted that in this case, the voltage Vr may be directly associated with the state of the substance.

In the information processing devices 20, 22, 24, 25, the chips 100, 102 are set to be movable. Instead of this, the chips 200, 202 may be movable.

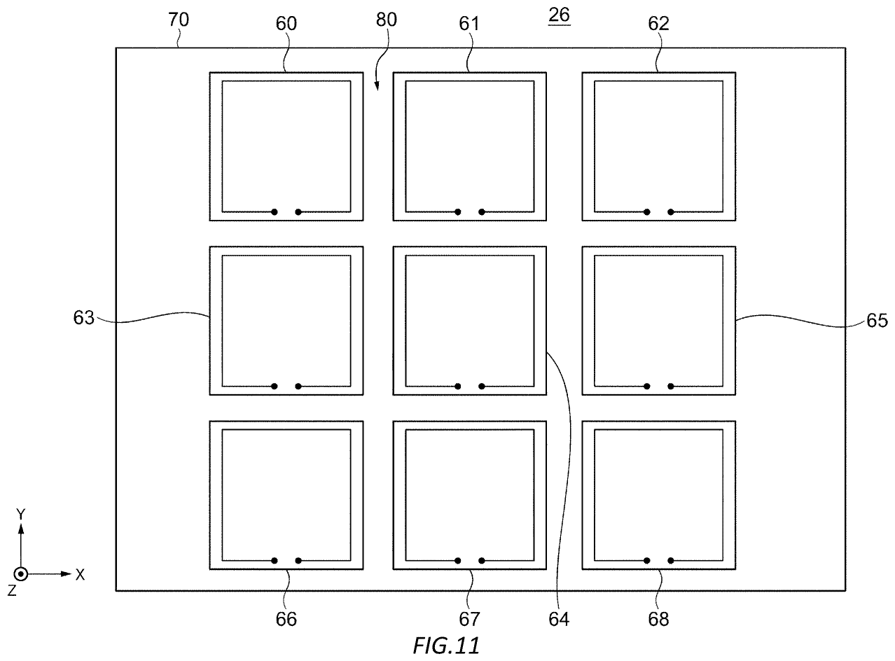

FIG. 11 schematically shows an information processing device 26 having three or more chips which are separate from each other. The information processing device 26 has nine chips aligned in groups of three in the XY directions. Each of nine chips 60 to 68 may be any of the chips 100, 102, 200, 202 shown in FIG. 2 and FIG. 8.

Among the nine chips, any may be movable and any may be fixed. For example, every other chip may be movable and fixed. Specifically, the chips 60, 62, 64, 66, 68 may be movable, and the chips 61, 63, 65, 67 may be fixed. An example of a movable mechanism is shown in FIG. 9.

In the above example of the movable and fixed chips, by the chip 64 moving in the X direction, the coupling coefficient k with the chip 63 and/or the chip 65 which are provided to be adjacent thereto on both sides in the X direction, is changed. By the chip 64 moving in the Y direction, the coupling coefficient k with the chip 61 and/or the chip 67 which are provided to be adjacent thereto on both sides in the Y direction, is changed. Therefore, with the information processing device 26, it is possible to detect movements of the chip 64 in both of the X direction and the Y direction. Accordingly, by using the method described in the information processing device 20, it is possible to respectively calculate the states of substances between the chip 64 and other chips which are adjacent thereto in the X direction and the Y directions.

As described above, the chip 64 communicates with the plurality of chips, for example, the chips 61, 63, 65, 67. In this case, communication may be performed in a time-division manner in predetermined order. Further, the signal that is communicated may include information for specifying the chip itself, or for specifying a positional relationship with the chip 64. This information may be stored in a storage unit on each chip. As described above, the pulse cycle is on the order of sub-nanoseconds, and thus even when communication is performed in the time-division manner, it is possible to calculate the change in the state of the substance by a temporal resolution on the order of microseconds.

It should be noted that in the information processing device 26 as well, the movable mechanism shown in FIG. 4 or FIG. 10 may be used instead of the movable mechanism shown in FIG. 9. Further, the movable mechanisms of FIG. 4, FIG. 9, and FIG. 10 may be mixed for each chip.

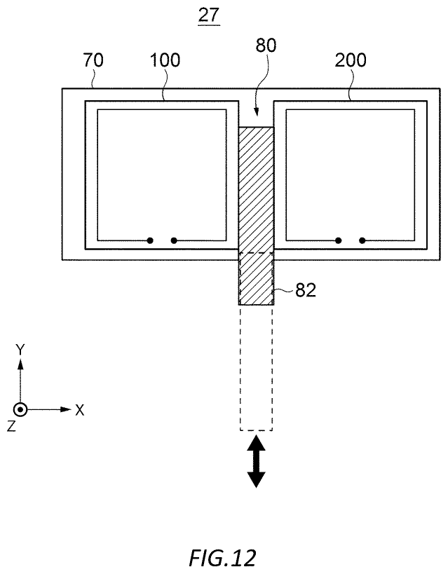

FIG. 12 schematically shows another information processing device 27 having two chips 100, 200 which are separate from each other. In the information processing device 27, the same configurations as those in the information processing device 20 are given the same reference signs numerals and the description thereof will be omitted.

In the information processing device 27, the chip 100 and the chip 200 are fixed onto the support member 70 with the gap 80 between them. That is, the relative positions of the chip 100 and the chip 200 are fixed.

When the substance 82 having magnetic permeability different from that of the surroundings, for example, air, enters the gap 80, the voltage Vr that is induced on the receiving side is changed in comparison with a case where the substance 82 does not exist. For example, when the magnetic permeability of the substance 82 is greater than that of air, the greater the volume of the substance 82 that enters the gap 80, the higher the voltage Vr.

Therefore, the voltage Vr on the receiving side, and an amount of the substance 82 inserted into the gap 80 in the Y direction in the figure, are associated with each other in advance, and are stored in the storage unit 232 as the table 234. In this manner, in the information processing device 27, as well, similar to the information processing device 20, by the communication of the magnetic field coupling from the chip 100 to the chip 200, the calculation circuit 230 calculates an insertion position as the state of the substance 82, based on the voltage Vr induced in the chip 200. In addition, while the information processing device 20 or the like detects the voltage Vr based on the positions of the chip 100 and the chip 200, the information processing device 27 detects the voltage Vr based on the magnetic permeability between the chip 100 and the chip 200.

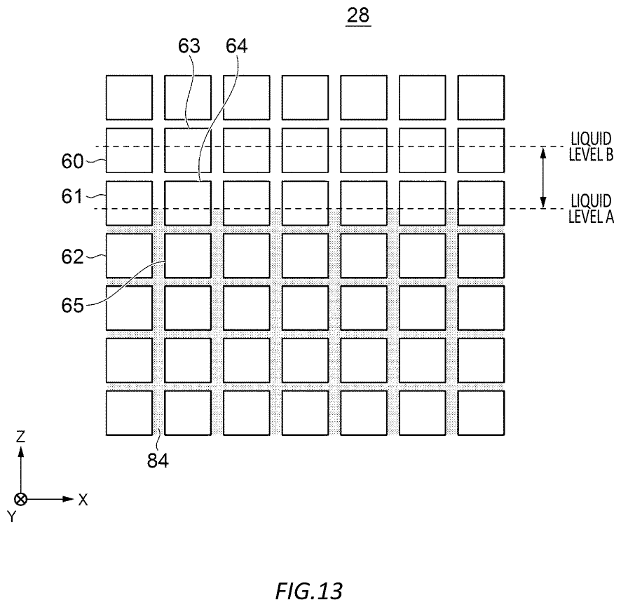

FIG. 13 schematically shows an information processing device 28 having three or more chips which are separate from each other. The information processing device 28 has 49 chips aligned in groups of seven in the X direction and a Z direction. Each of the 49 chips may be any of the chips 100, 102, 200, 202 shown in FIG. 2 and FIG. 8, and relative positions to each other are fixed.

The information processing device 28 is arranged, for example, along one side surface of a container into which a liquid 84 is put. Additionally, the liquid 84 is an example of the substance 82. The Z direction in FIG. 13 indicates a vertically upward direction.

In this manner, when the liquid 84 rises from a liquid level A to a liquid level B, air between the adjacent chips in a vicinity is gradually replaced by the liquid 84. For example, in a state of liquid level A, there is air between the chip 60 and the chip 63 which are adjacent to each other in the X direction; however, in a state of liquid level B, the gap is approximately half filled with the liquid 84. Therefore, by using the method described for the information processing device 27, it is possible for the information processing device 28 to calculate a position of the liquid level that is an example of the state of the substance between the chip 60 and the chip 63 which are adjacent to each other in the X direction.

For calculating the liquid level in the information processing device 28, it is also possible to use the chips 60, 61 which are adjacent to each other in the Z direction. Further, the information processing device 28 may calculate the position of the liquid level by using both of: the result of the calculation obtained by using the chips 60, 63 which are adjacent to each other in the X direction; and the result of the calculation obtained by using the chips 60, 61 which are adjacent to each other in the Z direction. Further, by using the chips 60, 61, 62, 63, 64, 65 aligned in the X direction and the Z direction, even in a case or the like where the liquid 84 is highly viscous or the like and the liquid level remains in a state of being tilted for a certain period of time, it is possible to measure the liquid level more accurately.

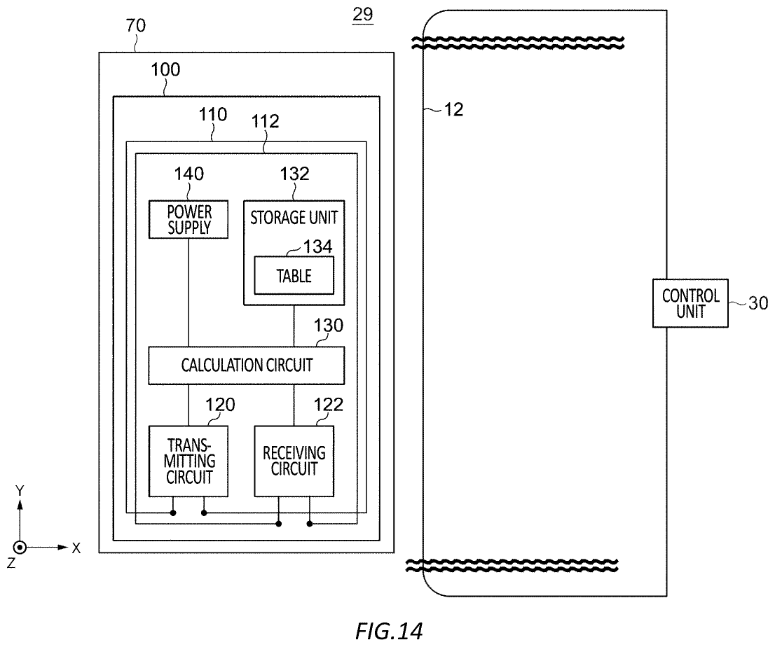

FIG. 14 schematically shows an information processing device 29 for which the chip 100, and the control unit 30 other than the chip, are used. In the information processing device 29, the same configurations as those in the information processing device 20 are given the same reference signs numerals and the description thereof will be omitted.

The information processing device 29 includes the chip 100, the control unit 30 other than the chip, and a coil 12 which is connected to the control unit 30 and extends to a position adjacent to the chip 100. In this manner, the chip 100 and the control unit 30 communicate with each other by the magnetic field coupling. In this case, as well, similar to the information processing device 20 or the like, it is possible to calculate the state of the substance between the chip 100 and the coil 12. It should be noted that in the information processing device 29, the chip 100 and the control unit 30 may be respectively on the transmitting side and the receiving side; or the control unit 30 and the chip 100 may be respectively on the transmitting side and the receiving side.

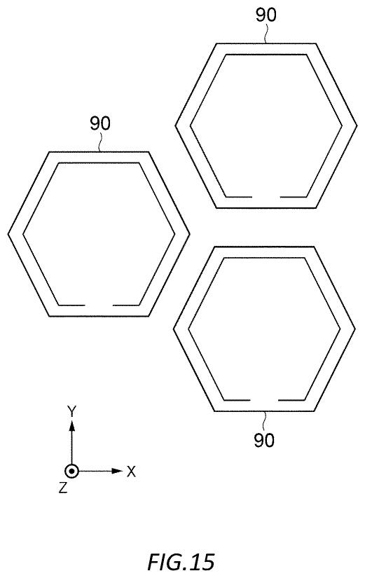

FIG. 15 shows another example of an outer shape of a chip 90. In FIGS. 1 to 14, the chip has a rectangular shape, and the coil also has an approximately rectangular shape. The chip and the coil may have other shapes. For example, like the chip 90, the chip may have a hexagonal plate-like outer shape, and the coil may also have an approximately hexagonal shape. The arrangement of a plurality of chips 90 may also be in a honeycomb shape.

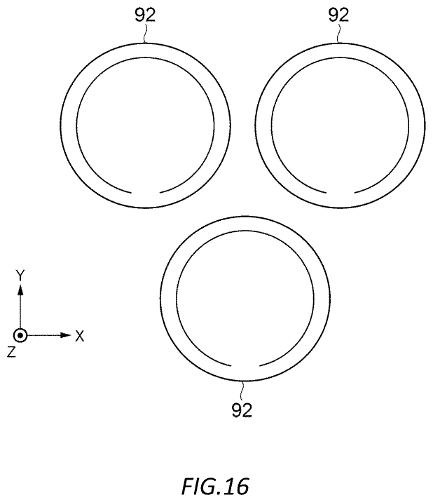

FIG. 16 shows another example of an outer shape of a chip 92. In the example of FIG. 16, the chip 92 has a circular plate-like outer shape, and the coil also has a circular shape.

A timing for starting and ending the calculation of the state of the substance may be specified by the user using the operation unit 40. Instead of this, a timer may be provided in the chip on the transmitting side to transmit a signal at a predetermined time interval; and according to this, a voltage is induced in the chip on the receiving side, and based on the voltage, the chip on the receiving side may perform the calculation. The results of the calculations may be output each time a calculation is performed, or may be stored in the storage unit 232 of the chip 200 on the receiving side to be output collectively at a predetermined timing.

The substance 82 arranged in a gap between the chips which are adjacent to each other may be any of a gas, a liquid, or a solid. When there is some correlation between the state of the substance 82, and the state of communication between the chips which are adjacent to each other, by associating them with each other in advance, it is possible to calculate the state of the substance 82 from the state of communication as described above. In addition to the volume, an example of the state of the substance 82 includes a temperature, a vibration, a pressure, an electromagnetic wave, a sound volume, humidity, or the like.

FIG. 7 has described the example of the voltage Vr that is induced on the receiving side, as the state of communication for calculating the state of the substance 82. The state of communication is not limited to this. For example, the state of communication may be a current flowing through a receiving circuit by the voltage Vr. As yet another example, the state of communication may be an “amplitude of a distortion of a waveform”.

The control unit 30 of the control apparatus 10 controls the state of the substance 82, based on the state of the substance 82 calculated by the information processing device 20 or the like, or the change in the state. That is, it is possible to configure a feedback system. For example, in the example of FIG. 13, the control unit 30 may receive information on the liquid level from the information processing device 29; and control an amount of liquid 84 flowing into and/or out of the container in which the information processing device 29 is provided. Instead of the above description, the control unit 30 of the control apparatus 10 may control the position of the movable chip 100 or a magnitude of the transmitting current, based on the state of the substance 82 calculated by the information processing device 20 or the like, or the change in the state.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. An information processing device comprising:
a first coil;
a second coil which is aligned along a surface on which the first coil is wound, and receives a signal transmitted from the first coil by magnetic field coupling; and
a calculation unit which calculates a state of a substance by detecting a state of communication between the first coil and the second coil, wherein
the substance is arranged in a gap between the first coil and the second coil, and
the state of communication is associated with a change in the substance.

2. The information processing device according to claim 1, wherein the calculation unit detects a change in the state of communication to calculate and output a change in the state of the substance.

3. The information processing device according to claim 1, wherein the first coil and the calculation unit are integrated as a first chip separate from the second coil.

4. The information processing device according to claim 3, wherein the calculation unit is arranged inside the first coil.

5. The information processing device according to claim 1, wherein
the first coil is provided to be movable based on a change in a volume of the substance that is arranged in the gap, and
the calculation unit calculates a value due to the change in the volume of the substance.

6. The information processing device according to claim 1, wherein information on the state of the substance calculated by the calculation unit, is transmitted to an outside by using at least one of the first coil or the second coil.

7. The information processing device according to claim 1, wherein the second coil is provided in a second chip separate from the first coil.

8. The information processing device according to claim 1, wherein the second coil and the calculation unit are integrated as a second chip separate from the first coil.

9. The information processing device according to claim 8, wherein the calculation unit is arranged inside the second coil.

10. The information processing device according to claim 1, wherein the first coil is provided to be movable based on a change in a volume of the substance that is arranged in the gap.

11. The information processing device according to claim 1, wherein the first coil transmits at least one of a position or identification information of the first coil.

12. A control apparatus comprising:
the information processing device according to claim 1; and
a control unit which controls the state of the substance, wherein
the control unit controls the state of the substance based on information on the state of the substance calculated by the calculation unit.

13. An information processing device comprising:
a first coil;
a second coil which receives a signal transmitted from the first coil by magnetic field coupling;
a support portion which supports the first coil and the second coil; and
a calculation unit which detects a state of communication between the first coil and the second coil, and calculates a state of a substance that is arranged in a gap between the first coil and the second coil and that is separate from the support portion, wherein
the state of communication is associated with the state of the substance in advance.
